(19) United States
(12) Patent Application Publication
(10) Pub. No.: US 2016/0192510 A1
(43) Pub. Date: Jun. 30, 2016

(54) INJECTION-MOLDED CASE FOR ELECTRONIC COMMUNICATION PRODUCTS

(71) Applicant: Doria International, Inc., Shenzhen (CN)

(72) Inventor: Xuyu LUO, Shenzhen (CN)

(73) Assignee: Doria International, Inc., Shenzhen (CN)

(21) Appl. No.: 15/064,051

(22) Filed: Mar. 8, 2016

(30) Foreign Application Priority Data
Dec. 15, 2014 (CN) 201420795128.7

(51) Int. Cl. H05K 5/00; H05K 5/04

(52) U.S. Cl. CPC H05K 5/0004; H05K 5/04

(57) ABSTRACT

The present utility model provides a twice injection-molded frame structure for electronic communication products, which comprises a metal housing connected by injection-molding and an inner frame made of soft plastics. The metal housing is divided into three sections and has metal keys molded individually. Holes are provided in the soft plastic inner frame in locations corresponding to the metal keys, and key-blocking cloth is provided within the holes. When the aluminum alloy frame and TPE use a bonding-fusion process in production hard-to-hard contact between metals is avoided (which contact would result in surface scratches on the machine); instead when TPE is in contact with the metal of the machine, it has further effects of avoiding collision and shock absorption. That the aluminum alloy frame and TPE use the bonding-fusion process in production sufficiently resolves the defect that frame products cannot be surface treated. There is no risk to scratch the machine when the product is assembled with the machine.

### CROSS-REFERENCE TO RELATED APPLICATIONS

Pursuant to 35 U.S.C. §119(a), this application claims the benefit of earlier filing date and right of priority to Chinese Patent Application No. 201420795128.7, filed on Dec. 15, 2014, the contents of which are hereby incorporated by reference herein in its entirety.

### TECHNICAL FIELD

The present utility model relates to the field of accessories of electronic communication products, and particularly relates to a twice injection-molded structure of a metal frame with TPE/TPU.

### BACKGROUND

Frame structures, among accessories of electronic communication products, are now widely used in mobile phones and peripheral digital electronic products. At present, the vast majority of the frame products on the market are over-molded (twice injection-molded) products, which are made from the combinations of materials such as PC+TPE or PC+TPU for lagging. Such over-molded products can be conveniently produced due to their good fusion and plasticity properties. However, a plastic product may generate burrs at a high temperature during the molding process and after being molded, problems such as deformation and cracks may occur because of the specific characteristic of the materials. Besides, a PC product cannot be subjected to a sandblasting or oxidation process and thus cannot obtain metallic effects. In general, a frame as a protection is directly made of pure aluminum alloy by a CNC (Computer Numerical Control). However, since aluminum alloy itself is metal and many machines also have a metal housing, the machines may be scratched by such hard-to-hard contact.

### Contents of the Utility Model

To solve the problem existing in the prior art, the present utility model provides a twice injection-molded frame structure for electronic communication products, which comprises a metal housing connected by injection-molding and an inner frame made of soft plastics, wherein the metal housing is divided into three sections and has metal keys molded individually , holes are provided in the soft plastic inner frame in locations corresponding to the metal keys, and key-blocking cloth is provided within the holes.

As a further improvement of the present utility model, the three sections of the metal housing are a top frame, a left frame and a right frame.

As a further improvement of the present utility model, two ends of the top frame extend in arc segments which connect to the left frame and right frame.

As a further improvement of the present utility model, an end of the left frame and an end of the right frame extend, respectively, in an arc segment which forms a portion of the bottom frame.

As a further improvement of the present utility model, the key-blocking cloth and the soft plastic inner frame are connected by adhesion.

The present utility model has benefits as follows:

When the aluminum alloy frame and TPE use a bonding-fusion process in production, hard-to-hard contact between metals is avoided (which contact would result in surface scratches on the machine); instead when TPE is in contact with the metal of the machine, it has further effects of avoiding collision and shock absorption. That the aluminum alloy frame and TPE use the bonding-fusion process in production sufficiently resolves the defect that frame products cannot be surface treated. There is no risk to scratch the machine when the product is assembled with the machine.

By seamlessly adhering thermoplastic polyurethane rubber TPE and the aluminum alloy through over-molding and dividing the aluminum alloy into three sections, difficulty in production is decreased while it becomes easier to handle the problem of burrs. The subject product utilizes a structure with a soft material and a rigid material and has a sectional processing on the aluminum alloy so as to make the TPE soft material seamlessly adhered, also overcoming the problems of deformation and crack.

### DESCRIPTION OF THE FIGURES

FIG. 1 is a schematic diagram of the perspective structure of the present utility model;

FIG. 2 is a schematic diagram of the perspective structure of the present utility model viewed from another direction; and

FIG. 3 is an exploded view of the present utility model.

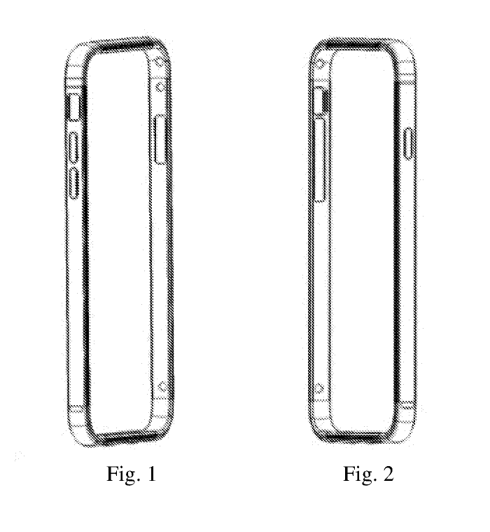

### MODE OF CARRYING OUT THE UTILITY MODEL

The following are further descriptions of the present utility model in conjunction with the accompanying drawings.

Thermal plastic elastomer is referred to as “TPE,” poly carbonate is referred to “PC” and thermoplastic polyurethane is referred to as “TPU.”

Through repeated experiments, the present utility model achieves success by means of adopting a RaO-carved aluminum alloy material and thermoplastic polyurethane rubber TPE for over-molding. By using techniques for over-molding the aluminum alloy and thermoplastic polyurethane rubber TPE, techniques for positioning the aluminum alloy in mold, techniques for in-mold injection-molding to prevent the thermoplastic polyurethane rubber TPE from deforming, and techniques for fusion-bonding metal materials and plastic materials, the present utility model repeatedly conducted adjustments and tried new element ratio over traditional materials to resolve undesirable problems such as fragile bonding, deformation, cracks and burr currently occurring in the over-molded product during the procedure of fusion bonding metal materials and plastic materials. Based on the new structure, the over-molded combination of the metal and plastic materials can be obtained by the fusion bonding technique. Since one material of the product is a metal and the other material of the product is a soft material, high precision is demanded during the molding procedure, and typically tolerance error is limited to the range from 0.01 to 0.03 mm.

By using a seamlessly adhesive over-molded (twice injection-molded) structure of the thermoplastic polyurethane rubber TPE (TPU) and the aluminum alloy, and by dividing the aluminum alloy into three sections, the problem of burrs can be easily handled while production difficulty is decreased. The subject product utilizes a structure with a soft material and a rigid material, and uses a sectional treatment on the aluminum alloy so as to make the TPE soft material seamlessly adhered, also overcoming the problems of deformation and crack and better facilitating the assembly and disassembly of the product with or from a machine.

By using an over-molded (twice injection-molded) structure having thermoplastic polyurethane rubber TPE and aluminum alloy, users do not need to worry about the problem that the product is so soft that it could be deformed easily or so hard as to be brittle and easy to crack (which may hurt users' hand), and can enjoy the high-end visual and touch feeling usually associated with metal when aluminum alloy is over-molded with TPE.

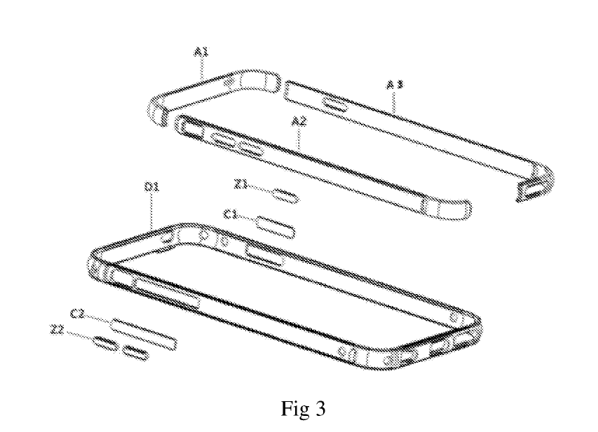

As shown in FIG. 3:

A1-A3 are the outer frames which are made of an aluminum alloy;

Z1-Z2 are the metal keys which are made of an aluminum alloy;

C1-C2 are the key-blocking cloth which is made of supebric flannel; and

D1 is the soft plastic inner frame which is made of TPE or TPU.

A1-A3 and Z1-Z2 are metal components. They are produced from roughs of a size required by finished products. The roughs are made via an extruding process at a high temperature from aluminum, and then passed through a CNC, where the roughs are processed by the CNC according to instructions from the decode control digital unit of a computer as required for the products. As the CNC is programmed to perform required actions, the roughs are cut into the half-finished components by a cutter. Then, the half-finished components are put in the mold to carry out a series of debugging such as position and data. If this debugging is OK, the solution of thermoplastic polyurethane rubber TPE is injected by an injection-molding machine to conduct molding and splicing treatments. After cooling, the product is taken out and put on a fine-machining assembly line for the processing of pasting the blocking cloth manually. Finally, the product is finished.

The above contents are further detailed descriptions of the present utility model in conjunction with specific preferred embodiments, and it cannot be regarded that specific implementation of the present utility model is limited by the descriptions. It will be appreciated by a person skilled in the art that numerous simple deductions or replacements may be made to the above-described embodiments, which should be considered within the scope of the present utility model without departing from the conception of the present utility model.

1. A twice injection-molded frame structure for electronic communication products, characterized in that:
it comprises a metal housing connected by injection-molding and an inner frame made of soft plastics;
the metal housing is divided into three sections and has metal keys molded individually;
holes are provided in the soft plastic inner frame in locations corresponding to the metal keys;
and key-blocking cloth is provided within the holes.

2. The twice injection-molded frame structure for electronic communication products as recited in claim 1, characterized in that:
the three sections of the metal housing are a top frame, a left frame and a right frame.

3. The twice injection-molded frame structure for electronic communication products as recited in claim 2, characterized in that:
two ends of the top frame extend in arc segments which connect to the left frame and right frame.

4. The twice injection-molded frame structure for electronic communication products as recited in claim 2, characterized in that:
an end of the left frame and an end of the right frame extend, respectively, in an arc segment which forms a portion of the bottom frame.

5. The twice injection-molded frame structure for electronic communication products as recited in claim 1, characterized in that:
the key-blocking cloth and the soft plastic inner frame are connected by adhesion.
